(19) United States
(12) Patent Application Publication
(10) Pub. No.: US 2004/0094197 A1
(43) Pub. Date: May 20, 2004

(54) Photovoltaic device comprising a 1,3,5-tris-aminophenyl-benzene compound

(75) Inventors: Hieronymus Andriessen, Beerse (BE); Joop Van Deelen, Petten (NL); Martijn Wienk, Tilburg (NL); Jan Kroon, Alkmaar (NL)

Correspondence Address: LEYDIG VOIT & MAYER, LTD, TWO PRUDENTIAL PLAZA, SUITE 4900, 180 NORTH STETSON AVENUE, CHICAGO, IL, 60601-6780, US

(73) Assignee: AGFA-GEVAERT, Mortsel (BE)

(21) Appl. No.: 10/657,894

(22) Filed: Sep. 9, 2003

Related U.S. Application Data
(60) Provisional application No. 60/411,555, filed on Sep. 18, 2002.

(30) Foreign Application Priority Data
Sep. 10, 2002 (WO) PCT/EP02/10120

(51) Int. Cl. H01L 31/00

(52) U.S. Cl. 136/263; 257/40

(57) ABSTRACT

A photovoltaic device comprising a n-type semiconductor with a band-gap of greater than 2.9 eV, a spectral sensitizer and a 1,3,5-tris-aminophenyl-benzene compound represented by formula (I):

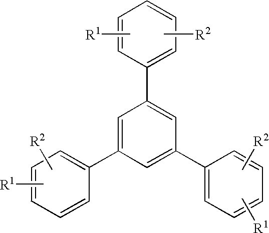

wherein R¹ represents a —NR³R⁴ group, wherein R³ and R⁴, same or different represent an unsubstituted C₂-C₁₀ alkyl group, a substituted C₂-C₁₀ alkyl group, a benzyl group, an unsubstituted cycloalkyl group, a substituted cycloalkyl group, an unsubstituted aryl group or a substituted aryl group, and R² represents hydrogen, an alkyl group including a substituted alkyl group or halogen; and the 1,3,5-tris-aminophenyl-benzene compound is optionally in a cationic form; and a process for preparing the above-mentioned photovoltaic device with at least one transparent electrode comprising the steps of: providing a support with a conductive layer as one electrode; coating the conductive layer on the support with a layer comprising the n-type semiconductor with a bandgap of greater than 2.9 eV; coating the n-type semiconductor-containing layer with a solution or dispersion comprising the 1,3,5-tris-aminophenyl-benzene compound, or cation thereof, to provide after drying a layer comprising the 1,3,5-tris-aminophenyl-benzene compound; and applying a conductive layer to the layer comprising the 1,3,5-tris-aminophenyl-benzene compound thereby providing a second electrode.

This application claims the benefit of U.S. Provisional Application No. 60/411,555 filed Sep. 18, 2002, which is incorporated by reference. In addition, this application claims the benefit of International Application No. PCT/EP 02/10120 filed Sep. 10, 2002, which is also incorporated by reference.

### FIELD OF THE INVENTION

The present invention relates to a photovoltaic device comprising a 1,3,5-tris-aminophenyl-benzene compound optionally in a cationic form.

### BACKGROUND OF THE INVENTION

There are two basic types of photoelectrochemical photovoltaic cells. The first type is the regenerative cell which converts light to electrical power leaving no net chemical change behind. Photons of energy exceeding that of the band gap generate electron-hole pairs, which are separated by the electrical field present in the space-charge layer. The negative charge carriers move through the bulk of the semiconductor to the current collector and the external circuit. The positive holes are driven to the surface where they are scavenged by the reduced form of the redox relay molecular (R), oxidizing it: h⁺+R→O, the oxidized form. O is reduced back to R by the electrons that re-enter the cell from the external circuit. In the second type, photosynthetic cells, operate on a similar. principle except that there are two redox systems: one reacting with the holes at the surface of the semiconductor electrode and the second reacting with the electrons entering the counter-electrode. In such cells water is typically oxidized to oxygen at the semiconductor photoanode and reduced to hydrogen at the cathode. Titanium dioxide has been the favoured semiconductor for these studies.

Mesoscopic or nano-porous semiconductor materials, minutely structured materials with an enormous internal surface area, have been developed for the first type of cell to improve the light capturing efficiency by increasing the area upon which the spectrally sensitizing species could adsorb. Arrays of nano-crystals of oxides such as TiO₂, ZnO, SnO₂ and Nb₂O₅ or chalcogenides such as CdSe are the preferred semiconductor materials and are interconnected to allow electrical conduction to take place. These fundamental techniques were disclosed in 1991 by Graetzel et al. in Nature, volume 353, pages 737-740 and in U.S. Pat. No. 4,927,721, U.S. Pat. No. 5,350,644 and JP-A 05-504023. Graetzel et al. reported solid-state dye-sensitized mesoporous TiO₂ solar cells with up to 33% photon to electron conversion efficiencies.

EP-A 1 176 646 discloses a solid state p-n heterojunction comprising an electron conductor and a hole conductor, characterized in that it further comprises a sensitizing semiconductor, said sensitizing semiconductor being located at an interface between said electron conductor and said hole conductor; and its application in a solid state sensitized photovoltaic cell.

There is therefore a requirement for thermally stable organic hole-conducting compounds capable of forming stable transparent layers and being compatible with solid state photovoltaic cell configurations.

EP 0 349 034 discloses a chemical compound corresponding to the following general formula:

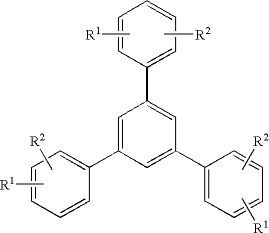

wherein R¹ represents a —NR³R⁴ group, wherein R³ and R⁴, same or different, represents a C₂-C₁₀ alkyl group including said alkyl groups in substituted form, a benzyl group, a cycloalkyl group, or an aryl group, and R² represents hydrogen, an alkyl group including a substituted alkyl group or halogen. Such compounds exhibit hole transport properties as described in 1993 by Novo et al. in 1993 in Phys. Stat. Solidi(B), volume 177, page 223, and by Van der Auweraer et al. in Journal of Physical Chemistry, volume 97, page 8808. In addition such compounds form thermally stable amorphous layers with glass transition temperatures greater than 100° C. as reported by Inada et al. in 1993 in Journal of Materials Chemistry, volume 3, pages 319-32.0. This combination of properties render such starburst compounds particularly interesting for use in organic electroluminescent devices as reported in 1996 by Inada et al. in Mol. Cryst. Liq. Cryst., volume 280, pages 331-336, and in 1997 by Shirota et al. in Journal of Luminescence, volumes 72-74, pages 985-991.

DE 19711713A discloses a photovoltaic cell, characterized in that said photovoltaic cell comprises an electrolyte which contains a hole-conducting compound as redox system e.g. a dissolved spiro or heterospiro hole conductor compound represented by formula (I):

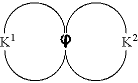

wherein φ is C, Si, Ge or Sn, and K¹ and K² are, independently of one another, conjugate systems, as redox system, and wherein the electrolyte is in a liquid state.

U.S. Pat. No. 5,487,953 discloses an organic electroluminescent device comprising a cathode, an emitting layer of organic compound, a hole transport layer of organic compound and an anode which are laminated in sequence, wherein said hole transport layer is made of a triphenylbenzene derivative represented by the following formula (1):

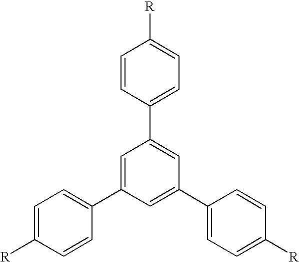

where R each independently represents one of functional groups represented by (Ra), (Rb) and (Rc):

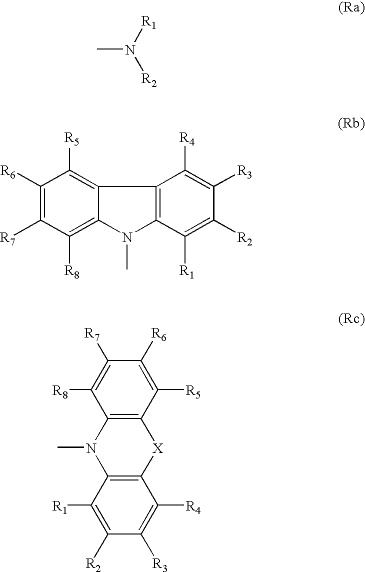

where R₁-R₈ denote independently a hydrogen atom, an alkyl group, an aryl group, an alkoxy group, an acyl group or an aralkyl group, and X denotes an oxygen atom, a sulfur atom or a selenium atom.

In 1997, J. Hagen et al. reported in Synthetic Metals, voleme 89, pages 215-220, a novel three-layer concept for efficient solidstate solar cells, such hydrid devices consist of an inorganic nanocrystalline titanium dioxide layer for electron conduction, a surface-adsorbed ruthenium dye complex for light absorption, and a layer of N,N′-diphenyl, N,N′-bis(p-methoxyphenyl)-benzidine for the transport of holes. They reported that such devices had external quantum efficiencies of up to 0.2%.

In 1997 K. Ito et al. reported in the IEEE Transactions on Electron Devices, volume 44, pages 1218-1211, the fabrication of a double layer organic electroluminescent (EL) device using a novel starburst molecule, 1,3,5-tris[N-(4-diphenylaminophenyl)-phenylamino]benzene (p-DPA-TDAB) as a hole-transport material and tris(8-quinolinato)-aluminium (Alq₃) as an emitting material and an investigation of its performance characteristics. They reported that p-DPA-TDAB functioned as a good hole-transport material and that the EL device was thermally stable when operated at a temperature of 120° C.

### ASPECTS OF THE INVENTION

It is therefore an aspect of the present invention to provide a photovoltaic cell with a stable hole-conducting compound.

Further aspects and advantages of the invention will become apparent from the description hereinafter.

### SUMMARY OF THE INVENTION

It has been surprisingly found that by rendering tris-1,3,5-amino-phenyl-benzene in a cationic form, hole transporting properties were exhibited which rendered them compatible with solid state photovoltaic cell configurations e.g. with a microporous titanium dioxide lower.

Aspects of the present invention are realized by a photovoltaic device comprising a n-type semiconductor with a band-gap of greater than 2.9 eV and a 1,3,5-tris-aminophenyl-benzene compound represented by formula (I):

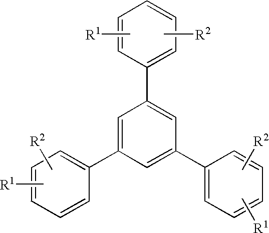

wherein R¹ represents a —NR³R⁴ group, wherein R³ and R⁴, same or different, represent an unsubstituted C₂-C₁₀ alkyl group, a substituted C₂-C₁₀ alkyl group, a benzyl group, an unsubstituted cycloalkyl group, a substituted cycloalkyl group, an unsubstituted aryl group or a substituted aryl group and R² represents hydrogen, an alkyl group including a substituted alkyl group or halogen; and the 1,3,5-tris-aminophenyl-benzene compound is optionally in a cationic form.

Aspects of the present invention are realized by a process for preparing the above-mentioned photovoltaic device with at least one transparent electrode comprising the steps of: providing a support with a conductive layer as one electrode; coating the conductive layer on the support with a layer comprising the n-type semiconductor with a bandgap of greater than 2.9 eV; coating the n-type semiconductor-containing layer with a solution or dispersion comprising the 1,3,5-tris-aminophenyl-benzene compound, or cation thereof, to provide after drying a layer comprising the 1,3,5-tris-aminophenyl-benzene compound; and applying a conductive layer to the layer comprising the 1,3,5-tris-aminophenyl-benzene compound thereby providing a second electrode.

Preferred embodiments are disclosed in the dependent claims.

### DETAILED DESCRIPTION OF THE INVENTION

### Definitions

The term chalcogenide means a binary compound containing a chalcogen and a more electropositive element or radical. A chalcogen is an element from group IV of the periodic table including oxygen, sulphur, selenium, tellurium and polonium.

The term “support” means a “self-supporting material” so as to distinguish it from a “layer” which may be coated on a support, but which is itself not self-supporting. It also includes any treatment necessary for, or layer applied to aid, adhesion to the support.

The term continuous layer refers to a layer in a single plane covering the whole area of the support and not necessarily in direct contact with the support.

The term non-continuous layer refers to a layer in a single plane not covering the whole area of the support and not necessarily in direct contact with the support.

The term coating is used as a generic term including all means of applying a layer including all techniques for producing continuous layers, such as curtain coating and doctor-blade coating, and all techniques for producing non-continuous layers such as screen printing, ink jet printing, flexographic printing.

The abbreviation PEDOT represents poly(3,4-ethylenedioxy-thiophene).

The abbreviation PSS represents poly(styrenesulphonic acid) or poly(styrenesulphonate).

### Photovoltaic Devices

Aspects of the present invention are realized by a photovoltaic device comprising a n-type semiconductor with a band-gap of greater than 2.9 eV and a 1,3,5-tris-aminophenyl-benzene compound represented by formula (I):

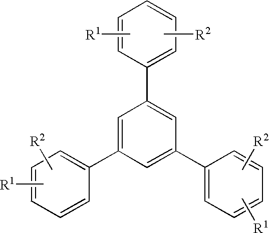

wherein R¹ represents a —NR³R⁴ group, wherein R³ and R⁴, same or different, represent an unsubstituted C₂-C₁₀ alkyl group, a substituted C₂-C₁₀ alkyl group, a benzyl group, an unsubstituted cycloalkyl group, a substituted cycloalkyl group, an unsubstituted aryl group or a substituted aryl group, and R² represents hydrogen, an alkyl group including a substituted alkyl group or halogen; and the 1,3,5-tris-aminophenyl-benzene compound is optionally in a cationic form.

Photovoltaic devices, according to the present invention, can be of two types: the regenerative type which converts light into electrical power leaving no net chemical change behind in which current-carrying electrons are transported to the anode and the external circuit and the holes are transported to the cathode where they are oxidized by the electrons from the external circuit and the photosynthetic type in which there are two redox systems one reacting with the holes at the surface of the semiconductor electrode and one reacting with the electrons entering the counter-electrode, for example, water is oxidized to oxygen at the semiconductor photoanode and reduced to hydrogen at the cathode. In the case of the regenerative type of photovoltaic cell, as exemplified by the solid state Graetzel cell. The charge transporting process can be ionic or electronic.

Such regenerative photovoltaic devices can have a variety of internal structures in conformity with the end use. Conceivable forms are roughly divided into two types: structures which receive light from both sides and those which receive light from one side. An example of the former is a structure made up of a transparently conductive layer e.g. an ITO-layer or a PEDOT/PSS-containing layer and a transparent counter electrode electrically conductive layer e.g. an ITO-layer or a PEDOT/PSS-containing layer having interposed therebetween a photosensitive layer and a charge transporting layer. Such devices preferably have their sides sealed with a polymer or an adhesive to prevent deterioration or volatilization of the inside substances. The external circuit connected to the electrically-conductive substrate and the counter electrode via the respective leads is well-known.

According to a first embodiment of the photovoltaic device, according to the present invention, the photovoltaic device comprises a single layer system.

According to a second embodiment of the photovoltaic device, according to the present invention, the photovoltaic device comprises a configuration in which the n-type semiconductor with a band-gap of greater than 2.9 eV is contiguous with the 1,3,5-tris-aminophenyl-benzene compound according to formula (I) or in which a spectral sensitizer is sandwiched between the n-type semiconductor with a band-gap of greater than 2.9 eV and the 1,3,5-tris-aminophenyl-benzene compound according to formula (I).

### 1,3,5-Tris-aminophenyl-benzene Compounds

A photovoltaic device comprising a n-type semiconductor with a band-gap of greater than 2.9 eV and a 1,3,5-tris-aminophenyl-benzene compound represented by formula (I):

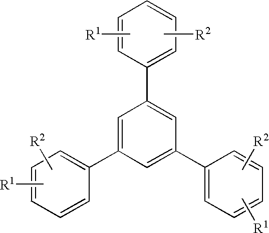

wherein R¹ represents a —NR³R⁴ group, wherein R³ and R⁴, same or different, represent an unsubstituted C₂-C₁₀ alkyl group, a substituted C₂-C₁₀ alkyl group, a benzyl group, an unsubstituted cycloalkyl group, a substituted cycloalkyl group, an unsubstituted aryl group or a substituted aryl group, and R² represents hydrogen, an alkyl group including a substituted alkyl group or halogen; and the 1,3,5-tris-aminophenyl-benzene compound is optionally in a cationic form. Preferred substituents for the C₂-C₁₀ alkyl group, cycloalkyl group and aryl group are alkyl groups, for example methyl, ethyl, propyl, butyl, pentyl, hexyl, heptyl, octyl, nonyl and decyl groups including all structural isomers thereof, alkoxy groups, for example methoxy, ethoxy, propoxy, butoxy, pentoxy, hexoxy groups and all structural isomers thereof, and carboxyester groups, for example —COOCH₃, —COOC₂H₅ and —COOC₃H₇ groups.

According to a third embodiment of the photovoltaic device, according to the present invention, the 1,3,5-tris-aminophenyl-benzene compound represented by formula (I) is selected from the group consisting of:

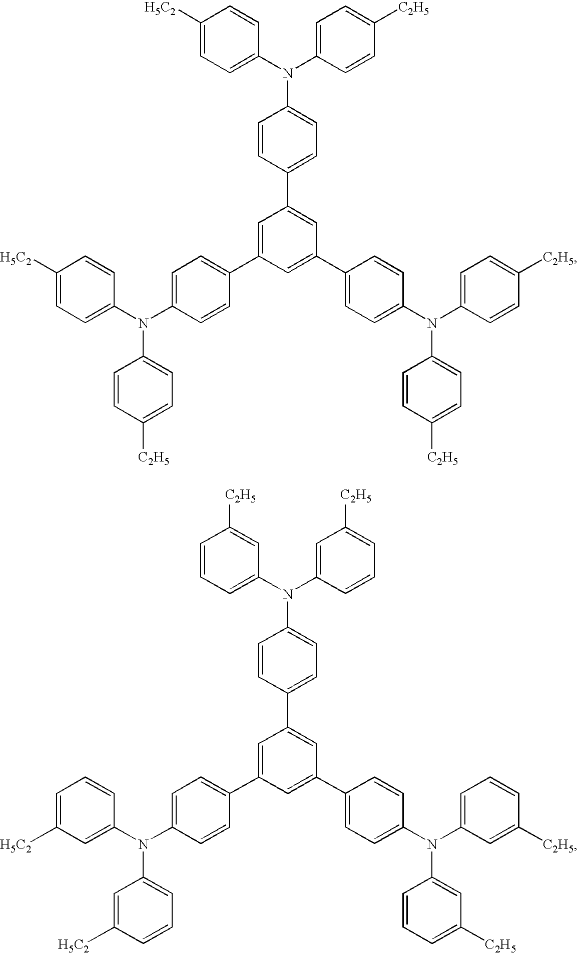

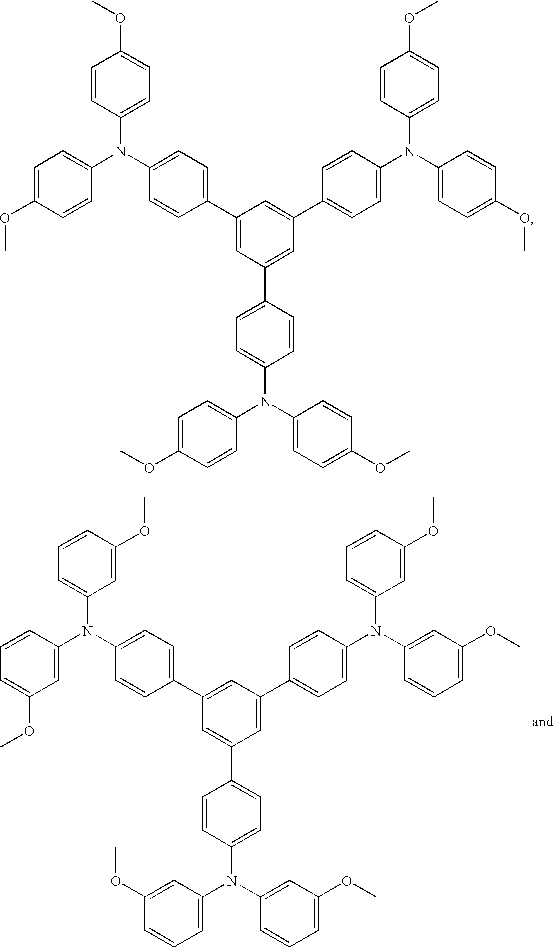

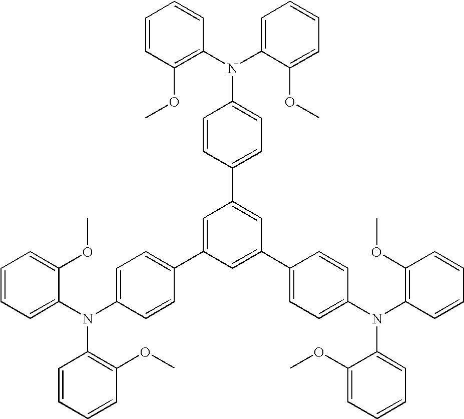

or the cations thereof.

Suitable 1,3,5-Tris-aminophenyl-benzene (TAPB) compounds, according to the present invention, include:

| | | E^{1/2}ₒₓ in |
|---|---|---|
| TAPB | | MeCN vs |
| compound | | sce [V]* |
| TAPB01 | 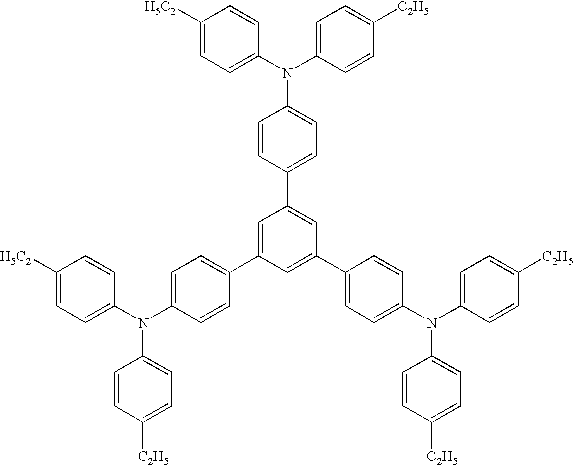 | 0.86 |
| TAPB02 | 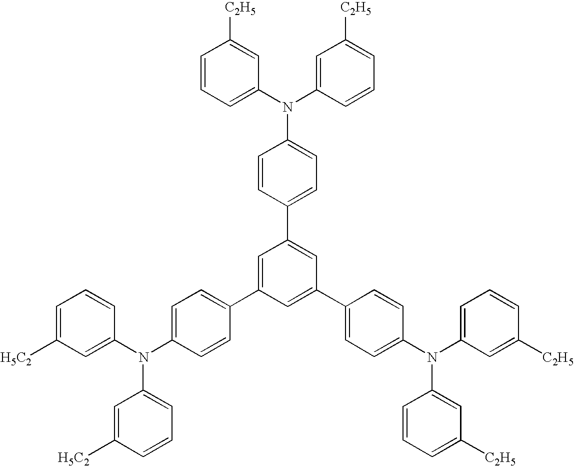 | 0.90 |
| TAPB03 | 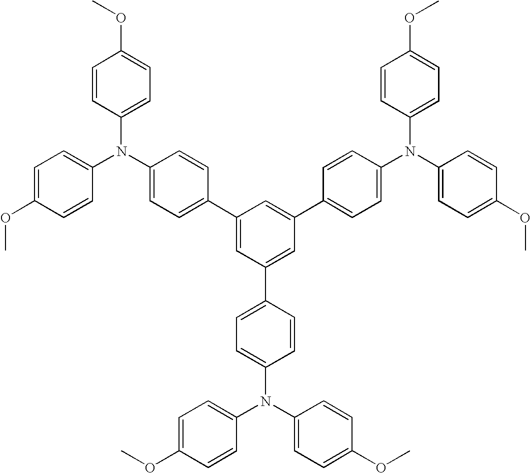 | 0.937 |
| TAPB04 | 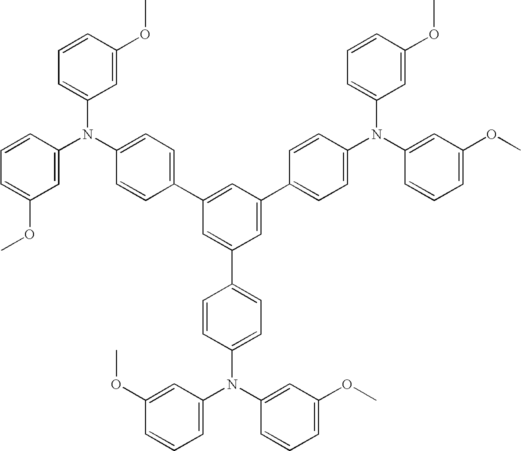 | 0.70 |
| TAPB05 | 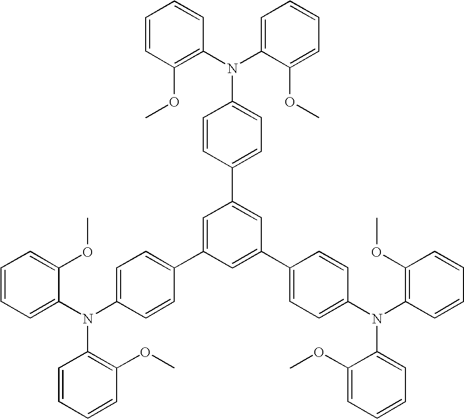 | — |
| TAPB06 | 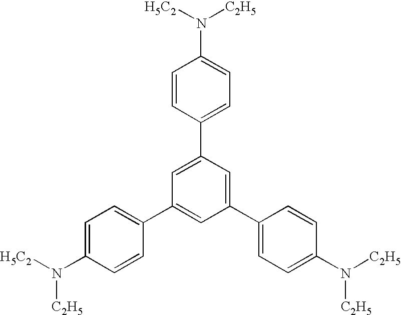 | 0.73 |
| TAPB07 | 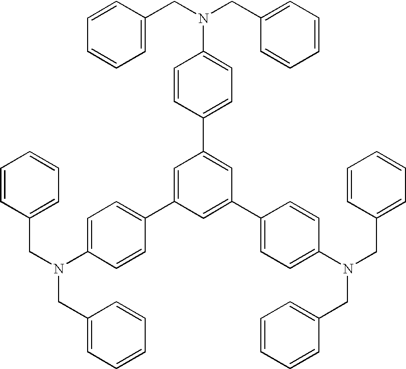 | 0.855 |
| TAPB08 | 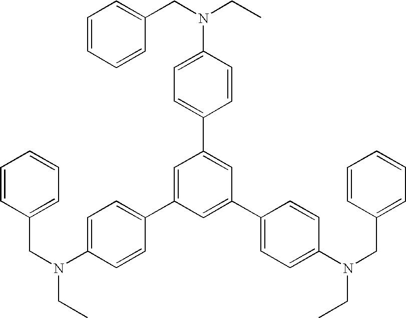 | 0.810 |
| TAPB09 | 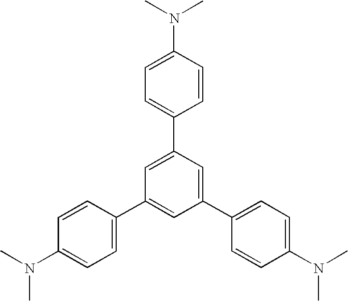 | — |
| TAPB10 | 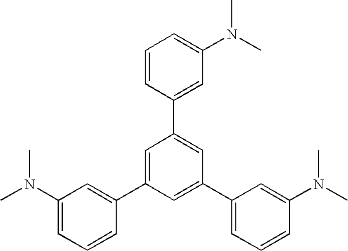 | 0.805 |
| TAPB11 | 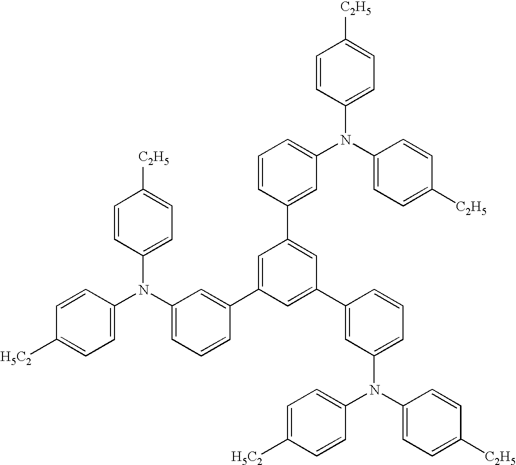 | 0.900 |
| TAPB12 | 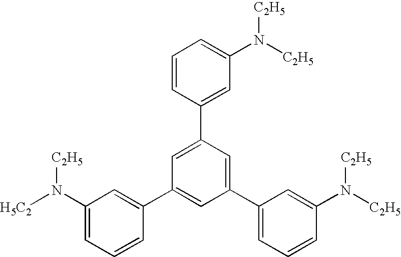 | 0.802 |
| TAPB13 | 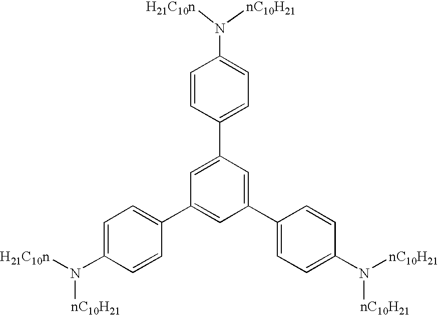 | — |
| TAPB14 | 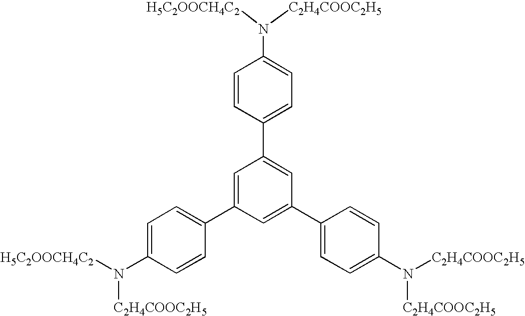 | — |

*reference ferrocene: 0.430 V

TAPB01 has a glass transition temperature of 107° C.

Cations of 1,3,5-tris-aminophenyl-benzene compounds according to formula (I) can be prepared by oxidation of the particular 1,3,5tris-aminophenyl-benzene compound with an oxidizing agent such as N(p-C₆H₄Br)₃SbCl₆.

### N-Type Semiconductors

According to a fourth embodiment of the photovoltaic device, according to the present invention, the n-type semiconductor has a bandgap of less than 6.0 eV.

According to a fifth embodiment of the photovoltaic device, according to the present invention, the n-type semiconductor is selected from the group consisting of titanium oxides, tin oxides, niobium oxides, tantalum oxides, tungsten oxides and zinc oxides. The n-type semiconductor may be porous or non-porous, although non-porous n-type semiconductors are preferred.

According to a sixth embodiment of the photovoltaic device, according to the present invention, the n-type semiconductor is titanium dioxide.

### Spectral Sensitization of N-Type Semiconductor Layers

According to a seventh embodiment of the photovoltaic device, according to the present invention, the photovoltaic device further contains at least one spectral sensitizer.

According to an eighth embodiment of the photovoltaic device, according to the present invention, the photovoltaic device further contains at least one spectral sensitizer selected from the group consisting of metal chalcogenide nano-particles with a band-gap of less than 2.9 eV and greater than 1.5 eV, organic dyes and metallo-organic dyes.

According to a ninth embodiment of the photovoltaic device, according to the present invention, the photovoltaic device further contains at least one spectral sensitizer selected from the group consisting metal oxides, metal sulphides and metal selenides.

According to a tenth embodiment of the photovoltaic device, according to the present invention, the photovoltaic device further contains one or more metal sulphides nano-particles with a band-gap of less than 2.9 eV and greater than 1.5 eV.

According to an eleventh embodiment of the photovoltaic device, according to the present invention, the photovoltaic device further contains one or more metal chalcogenide-nano-particles selected from the group consisting of lead sulphide, bismuth sulphide, cadmium sulphide, silver sulphide, antimony sulphide, indium sulphide, copper sulphide, cadmium selenide, copper selenide, indium selenide and cadmium telluride.

Vogel et al. in 1990 in Chemical Physics Letters, volume 174, page 241, herein incorporated by reference, reported the sensitization of highly porous TiO₂ with in-situ prepared-quantum size CdS particles (40-200 Å), a photovoltage of 400 mV being achieved with visible light and high photon to current efficiencies of greater than 70% being achieved at 400 nm and an energy conversion efficiency of 6.0% under monochromatic illumination with λ=460 nm. In 1994 Hoyer et al. reported in Applied Physics, volume 66, page 349, that the inner surface of a porous titanium dioxide film could be homogeneously covered with isolated quantum dots.

EP-A 1 176 646, herein incorporated by reference, discloses a solid state p-n heterojunction comprising an electron conductor and a hole conductor, characterized in that it further comprises a sensitizing semiconductor, said sensitizing semiconductor being located at an interface between said electron conductor and said hole conductor; and its application in a solid state sensitized photovoltaic cell. In a preferred embodiment the sensitizing semiconductor is in the form of particles adsorbed at the surface of said electron conductor and in a further preferred embodiment the sensitizing semiconductor is in the form of quantum dots, which according to a particularly preferred embodiment are particles consisting of PbS, CdS, Bi₂S₃, Sb₂S₃, Ag₂S, InAs, CdTe, CdSe or HgTe or solid solutions of HgTe/CdTe or HgSe/CdSe.

Suitable spectrally sensitizing organic dyes (SSOD) include cyanine, merocyanine and anionic dyes, such as:

| | |
|---|---|
| SSOD-01 | 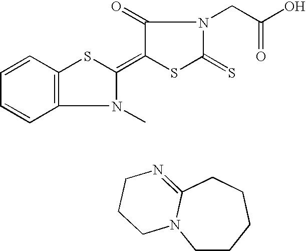 |
| SSOD-02 | 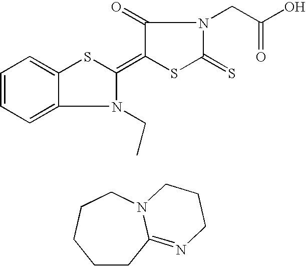 |
| SSOD-03 | 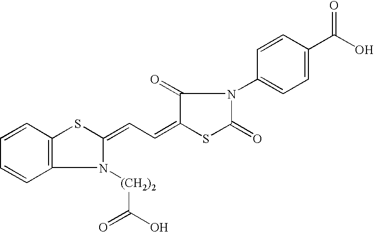 |
| SSOD-04 | 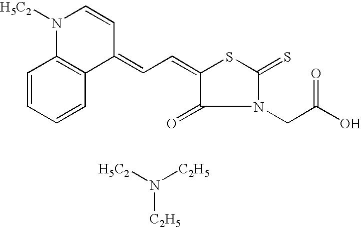 |
| SSOD-05 | 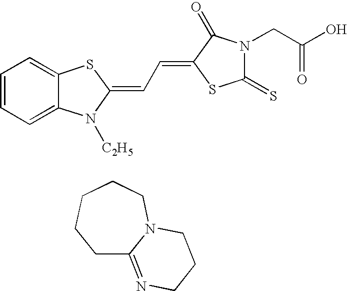 |

Suitable spectrally sensitizing metallo-organic dyes allowing for broad absorption of the solar spectrum include:

| | chemical name |
|---|---|
| Ruthenium 470, a | tris(2,2′bipyridyl-4,4′ dicarboxylato) |
| ruthenium dye from | ruthenium (II) dichloride |
| Solaronix | |
| Ruthenium 505, a | cis-bis(isocyanato) (2,2′bipyridyl-4,4′ |
| ruthenium dye from | dicarboxylato) ruthenium (II) |
| Solaronix | |
| Ruthenium 535*, a | cis-bis(isothiocyanato)bis(2,2′-bipyridyl- |
| ruthenium dye from | 4,4′-dicarboxylato) -ruthenium (II) |
| Solaronix | |
| Ruthenium 535 bis- TBA#, a ruthenium dye from Solaronix | cis-bis(isothiocyanato)bis(2,2′-bipyridyl- 4,4′-dicarboxylato) -ruthenium (II) bis- tetrabutylammonium 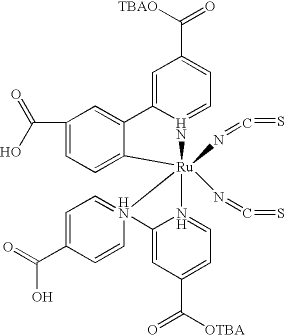 |
| Ruthenium 620 “Black | (anion only) tris(isothiocyanato) - |
| Dye”, a ruthenium dye | ruthenium (II) -2,2′:6′,2″-terpyridine- |
| from Solaronix | 4,4′,4″- tricarboxylic acid |

*previously known as SRS-HQ, N3
# previously known as MRS-HQ, N719, dye salt

### Process for Preparing a Photovoltaic Device

Aspects of the present invention are realized by a process for preparing a photovoltaic device, according to the present invention, with at least one transparent electrode comprising the steps of: providing a support with a conductive layer as one electrode; coating the conductive layer on the-support with a layer comprising the n-type semiconductor with a bandgap of greater than 2.9 eV, coating the n-type semiconductor-containing layer with a solution or dispersion comprising the 1,3,5-tris-aminophenyl-benzene compound, or cation thereof, to provide after drying a layer comprising the 1,3,5-tris-aminophenyl-benzene compound; and applying a conductive layer to the layer comprising the 1,3,5-tris-aminophenyl-benzene compound thereby providing a second electrode.

According to a first embodiment of the process, according to the present invention, the solution or dispersion of the 1,3,5-tris-aminophenyl-benzene compound according to formula (I) or cation thereof further contains a binder.

According to a second embodiment of the process, according to the present invention, the solution or dispersion of the 1,3,5-tris-aminophenyl-benzene compound according to formula (I) or cation thereof further contains an electrolyte. Suitable electrolytes include Li[(CF₃SO₂)₂N] and lithium trifluoromethanesulphonate (lithium triflate).

According to a third embodiment of the process, according to the present invention, the process further comprises the step of applying a solution or dispersion of a spectral sensitizer directly to the n-type semiconductor layer.

### Support

Supports for use according to the present invention include polymeric films, silicon, ceramics, oxides, glass, polymeric film reinforced glass, glass/plastic laminates, metal/plastic laminates, paper and laminated paper, optionally treated, provided with a subbing layer or other adhesion promoting means to aid adhesion to the layer configuration, according to the present invention. Suitable polymeric films are poly(ethylene terephthalate), poly(ethylene naphthalate), polystyrene, polyethersulphone, polycarbonate, polyacrylate, polyamide, polyimides, cellulose triacetate, polyolefins and poly(vinylchloride), optionally treated by corona discharge or glow discharge or provided with a subbing layer.

### Industrial Application

Layers of nano-porous metal oxide semiconductors with a band-gap of greater than 2.9 eV prepared according the process, according to the present invention, can be used in both regenerative and photosynthetic photovoltaic devices.

The invention is illustrated hereinafter by way of reference and invention photovoltaic devices. The percentages and ratios given in these examples are by weight unless otherwise indicated. Spiro-OMeTAD from SOLARONIX with the chemical name 2,2′7,7′-tetrakis(N,N-di-p-methoxyphenyl-amine)-9,9′-spirobifluorene was used as a reference material to check if the basic recipe and the configuration of the cell were in order.

### EXAMPLE 1

### Photovoltaic Devices with Solid State Organic Hole Conductor and High Temperature Sintered Nano-Porous TiO₂.

Photovoltaic Devices 1 to 3 were Prepared by the Following Procedure:

Preparation of the Front Electrode:

A glass plate (2×7 cm) coated with conductive SnO₂:F (Pilkington TEC15/3) with a surface conductivity of ca. 15 Ohm/square was ultrasonically cleaned in isopropanol for 5 minutes and then dried.

A small strip of SnO₂:F was removed to prevent short circuit. The glass electrode was partially covered with glass on the long side and a dense non-porous hole blocking titanium dioxide layer applied by spray pyrolysis of an ethanolic solution of di-isopropoxy titanium-bis (acetylacetone)in aerosol form as described by Kavan L. et al. In Electrochim. Acta (1995), 40(5), 643-52, herein incorporated by reference.

5 g of P25, a flame pyrolyzed nano-sized titanium dioxide with a mean particle size of 25 nm and a specific surface of 55 m²/g from DEGUSSA, was added to 15 mL of water followed by 1 mL of Triton X-100. The resulting titanium dioxide colloidal dispersion was cooled in ice and ultrasonically treated for 5 minutes. This dispersion was then doctor-blade coated onto the middle (0.7×4.5 cm²) of the electrode with the non-porous hole blocking titanium dioxide layer taped off at the borders. Nano-sized titanium dioxide dispersion-coated glass electrodes were heated at 450° C. for 30 minutes then cooled to 150° C. on a hot plate at 150° C. for 10 minutes thereby yielding a nano-porous TiO₂ layer thickness of 2 μm. After cooling is to 150° C., the nano-porous TiO₂ layer-coated glass electrode was immediately immersed in a 2×10⁻⁴ M solution of the Ruthenium 535 bis-TBA dye (from SOLARONIX) for 15 to 17 hours, followed by rinsing with acetonitrile to remove the non-adsorbed dye and drying at 50° C. for several minutes. The front electrode thereby produced was immediately used in assembling a photovoltaic cell.

### Coating with Layers of Hole Transporting Materials

Solutions of the Hole Transporting Materials were Prepared as Follows:

HTM solution 1:

60 mg (53.1 μmoles) of Spiro-OMeTAD was dissolved in 200 μl chlorobenzene (Aldrich) by heating for 1 hour at 70° C. 10.5 μl of a solution of 56.7 μg N(p-C₆H₄Br)₃SbCl₆ (69.4 nmoles) (Aldrich) and 907 μg Li[(CF₃SO₂)₂N] (3.16 μmoles) (Fluka) in acetonitrile were then added to this solution to give a HTM solution 1 0.25M in Spiro-OMeTAD, 0.33mM in N(p-C₆H₄Br)₃SbCl₆ and 15 mM in Li[(CF₃SO₂)₂N]

HTM Solution 2:

35 mg (35.8 μmoles) of TABP01 was dissolved in 200 μl chlorobenzene (Aldrich). To this solution, 10.5 μl of a solution of 56.7 mg N(p-C₆H₄Br)₃SbCl₆ (69.4 nmoles) (Aldrich) and 907 mg Li[(CF₃SO₂)₂N] (3.16 μmoles) (Fluka) in acetonitrile was then added to the solution to give to give a HTM solution 2 0.17M in TABP01, 0.33 mM in N(p-C₆H₄Br)₃SbCl₆ and 15 mM in Li[(CF₃SO₂)₂N].

HTM solution 3:

35.4 mg (35.8 μmoles) of TABP03 was dissolved in 200 μl chlorobenzene (Aldrich). To this solution, 10.5 μl of a solution of 56.7 mg N(p-C₆H₄Br)₃SbCl₆ (69.4 nmoles) (Aldrich) and 907 mg Li[(CF₃SO₂)₂N] (3.16 μmoles) (Fluka) in acetonitrile was then added to the solution to give to give a HTM solution 2 0.17M in TABP03, 0.33 mM in N(p-C₆H₄Br)₃SbCl₆ and 15 mM in Li[(CF₃SO₂)₂N].

N(p-C₆H₄Br)₃SbCl₆ oxidized the charge transport compound to its cationic salt, Li[(CF₃SO₂)₂N] acting as an electrolyte. Sufficient N(p-C₆H₄Br)₃SbCl₆ was present to ensure that the oxidation process went to completion as determined spectrophotometrically by monitoring, in the case of TABP01, the 397 nm, 695 nm and 772 nm peaks of the cationic state in analogy to the absorption spectrum reported in 1994 by Bonvoisin et al. in Journal of Physical Chemistry, volume 98, pages 5052-5057. Bonvoisin et al. reported that cyclic voltammetry and coulometry on TABP01 showed a unique, reversible, oxidation wave corresponding to a three-electron process, which was accompanied by the appearance of three bands at 397 nm, 695 nm and 772 nm respectively, corresponding to the tri-cation chromophore. TABP01 and TAPB03 appear to be oxidizable to their tri-cations i.e. all three nitrogens in the molecule are oxidizable, whereas in the case of Spiro-OMeTAD only two of the four nitrogens apppear to be oxidizable.

The front electrode was placed on the spincoater, the cover was closed and a flow of Argon was fed in for 2 minutes. About 150 μl of solution 1 was then dropped on the front electrode so as to cover the whole area. After waiting for 30 to 60 s for the drop to spread, the spincoater was again closed and again Argon flow was fed in for 1 minute. It took 5 s for the spincoater to accelerate to 1000 rpm at which speed the solution was allowed-to spin for 30 minutes.

The front electrode coated with the charge transport compound was then dried in the dark under Argon at 25° C. for 30 minutes followed by drying in a vacuum exicator for a further 30 minutes in dark. Finally a gold electrode was evaporated on top.

Measurements were only carried out after the photovoltaic device had stabilized in the dark at 25° C., which took between 1 and 24 hours. The same procedure was carried out for all six solutions. This resulted in PV devices 1, 2 and 3.

Photovoltaic Device Characterisation

The photovoltaic device configuration is shown in FIG. 1. The cell was irradiated with a Steuernagel Solar Constant 575 solar simulator with a metal halide 1 AM light source. The simulator was adjusted to about 1 sunequivalent. The electricity generated was recorded with a Type 2400 SMU Keithley electrometer in the voltage range −1 to +1 volt.

Table 1 lists the short circuit current (Isc) and open circuit voltage (Voc) for the devices. The active area was 0.14 cm².

TABLE 1

| photovoltaic device | hole transporting material | Isc (μA/cm²) | Voc (mV) |
|---|---|---|---|
| 1 (ref.) | Spiro-OMeTAD | 2880 | 795 |
| 2 (inv.) | TAPB01 | 11 | 585 |
| 3 (inv.) | TAPB03 | 4 | 475 |

Photovoltaic devices 2 and 3 with 1,3,5-tris-aminophenyl-benzene compounds TAPB01 and TAPB03 in a tri-cationic form and heat sintered titanium dioxide exhibit photovoltaic effects exhibit photovoltaic effects.

### EXAMPLE 2

### Photovoltaic Devices with Solid State Organic Hole Conductor and High Pressure Sintered Nano-Porous TiO₂

Photovoltaic Devices 4 to 6 were Prepared by the Following Procedure:

Photovoltaic devices 4 to 6 were prepared as described for Photovoltaic devices 1 to 3, except that-nano-titanium dioxide dispersion-coated glass electrode was first dried at 110° C. for 5 minutes, then, after cooling to room temperature, a pressure of 500 bars was applied for 5 seconds. This pressure sintered coating was then heated to 150° C., immediately immersed in a 2×10⁻⁴ M solution of the Ruthenium 535 bis-TBA dye and then washed and dried as described for Photovoltaic devices 1 to 3. Photovoltaic device 7 was prepared by the following procedure:

A 2×7 cm² piece of ITO-coated (from IST) with a surface resistivity of 70 Ohm/square was cleaned by rinsing in ethanol and ozone treatment. The electrode was partially covered with adhesive tape and put in an electron-beam apparatus. It was placed overnight in a vacuum with continuous pumping and the non-porous TiO₂ was applied locally to the substrate. After the deposition, the vacuum was released and the sample was ready to use.

5 g of DEGUSSA P25 titanium dioxide nano-particles was added to 15 mL of water and the resulting titanium dioxide colloidal dispersion cooled in ice and ultrasonically treated for 5 minutes.

This dispersion was then doctor-blade-coated onto the middle (0.7×4.5 cm²) of the non-porous hole blocking titanium dioxide layer taped off at the borders.

The coated PET electrode with the nano titanium dioxide dispersion was first dried at 110° C. for 5 minutes, then, after cooling to room temperature, a pressure of 500 bars was applied for 5 seconds. This pressure sintered coating was then heated to 150° C., immediately immersed in a 2×10⁻⁴ M solution of the Ruthenium 535 dye and the procedure described for Photovoltaic devices 1 to 3 followed. Finally layers of Spiro-OMeTAD and gold were applied as described for Photovoltaic device 1.

Table 2 lists the results for the different hole transporting materials with pressure sintered TiO₂ on a glass electrode and on an ITO-PET electrode.

TABLE 2

| Photovoltaic | | hole transporting | Isc | |
|---|---|---|---|---|
| device | Substrate | material | (μA/cm²) | Voc (mV) |
| 4 (ref.) | Glass/SnO2 | Spiro-OMeTAD | 20 | 735 |
| 5 (inv.) | Glass/SnO2 | TAPB01 | 0.66 | 215 |
| 6 (inv.) | Glass/SnO2 | TAPB03 | 0.71 | 385 |
| 7 (ref.) | PET/ITO | Spiro-OMeTAD | 5 | 585 |

Photovoltaic devices 5 and 6 with 1,3,5-tris-aminophenyl-benzene compounds TAPB01 and TAPB03 in a tri-cationic form and pressure sintered titanium dioxide exhibit photovoltaic effects, which are much closer to the performance of the reference photovoltaic device with Spiro-OMeTAD than for photovoltaic devices with heat sintered titanium dioxide.

The present invention may include any feature or combination of features disclosed herein either implicitly or explicitly or any generalisation thereof irrespective of whether it relates to the presently claimed invention. In view of the foregoing description it will be evident to a person skilled in the art that various modifications may be made within the scope of the invention.

Having described in detail preferred embodiments of the current invention, it will now be apparent to those skilled in the art that numerous modifications can be made therein without departing from the scope of the invention as defined it the following claims.

All references, including publications, patent applications, and patents, cited herein are hereby incorporated by reference to the same extent as if each reference were individually and specifically indicated to be incorporated by reference and were set forth in its entirety herein.

The use of the terms “a” and “an” and “the” and similar referents in the context of describing the invention (especially in the context of the following claims) are to be construed to cover both the singular and the plural, unless otherwise indicated herein or clearly contradicted by context. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the invention and does not pose a limitation on the scope of the invention unless otherwise claimed. No language in the specification should be construed as indicating any non-claimed element as essential to the practice of the invention.

Preferred embodiments of this invention are described herein, including the best mode known to the inventors for carrying out the invention. Of course, variations of those preferred embodiments will become apparent to those of ordinary skill in the art upon reading the foregoing description. The inventors expect skilled artisans to employ such variations as appropriate, and the inventors intend for the invention to be practised otherwise than as specifically described herein. Accordingly, this invention includes all modifications and equivalents of the subject matter recited in the claims appended hereto as permitted by applicable law. Moreover, any combination of the above-described elements in all possible variations thereof is encompassed by the invention unless otherwise indicated herein or otherwise clearly contradicted by context.

We claim:

1. A photovoltaic device comprising a n-type semiconductor with a band-gap of greater than 2.9 eV and a 1,3,5-tris-aminophenyl-benzene compound represented by formula (I): 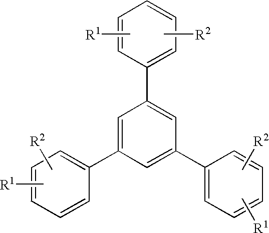
wherein R¹ represents a —NR³R⁴ group, wherein R³ and R⁴, same or different, represent an unsubstituted C₂-C₁₀ alkyl group, a substituted C₂-C₁₀ alkyl group, a benzyl group, an unsubstituted cycloalkyl group, a substituted cycloalkyl group, an unsubstituted aryl group or a substituted aryl group, and R² represents hydrogen, an alkyl group including a substituted alkyl group or halogen; and said 1,3,5-tris-aminophenyl-benzene compound is in a cationic form.

2. Photovoltaic device according to claim 1, wherein said 1,3,5tris-aminophenyl-benzene compound represented by formula (I) is selected from the group consisting of the cations of:

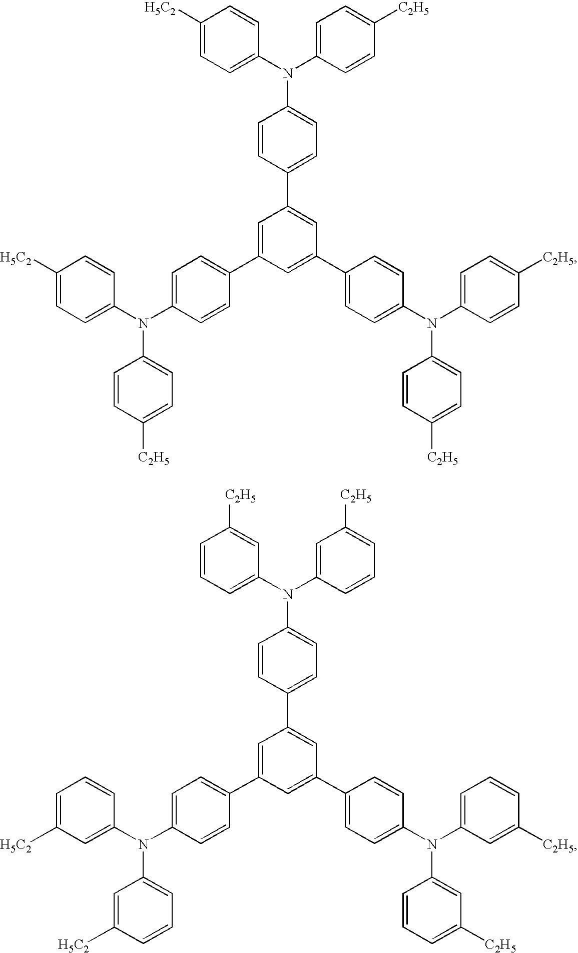

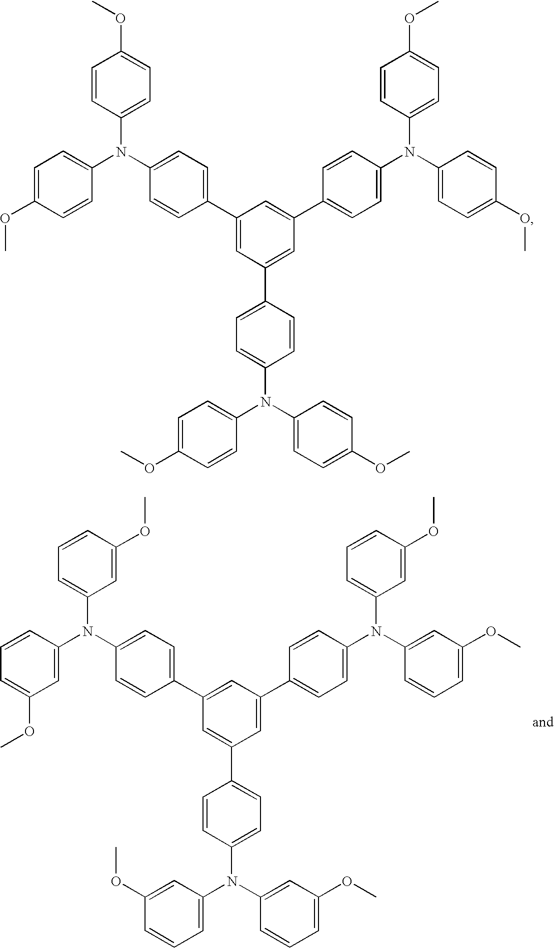

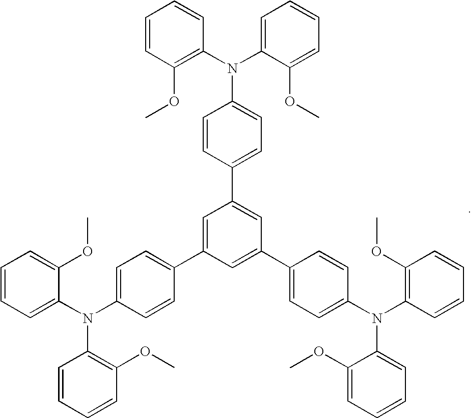

3. Photovoltaic device according to claim 1, wherein said n-type semiconductor is selected from the group consisting of titanium oxides, tin oxides, niobium oxides, tantalum oxides, tungsten oxides and zinc oxides.

4. Photovoltaic device according to claim 1, wherein said photovoltaic device further contains at least one spectral sensitizer.

5. Photovoltaic device according to claim 1, wherein said photovoltaic device further contains at least one spectral sensitizer selected from the group consisting of metal chalcogenide nano-particles with a band-gap of less than 2.9 eV, organic dyes and metallo-organic dyes.

6. Photovoltaic device according to claim 1, wherein said photovoltaic device further contains at least one spectral sensitizer selected from the group consisting metal oxides, metal sulphides and metal selenides.

7. A process for preparing a photovoltaic device comprising a n-type semiconductor with a band-gap of greater than 2.9 eV and a 1,3,5-tris-aminophenyl-benzene compound represented by formula (I): 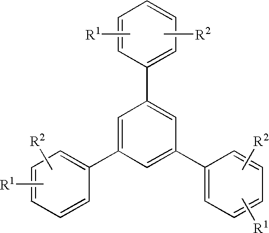
wherein R¹ represents a —NR³R⁴ group, wherein R³ and R⁴, same or different, represent an unsubstituted C₂-C₁₀ alkyl group, a substituted C₂-C₁₀ alkyl group, a benzyl group, an unsubstituted cycloalkyl group, a substituted cycloalkyl group, an unsubstituted aryl group or a substituted aryl group, and R² represents hydrogen, an alkyl group including a substituted alkyl group or halogen, and said 1,3,5-tris-aminophenyl-benzene compound is in a cationic form, with at least one transparent electrode comprising the steps of: providing a support with a conductive layer as one electrode; coating said conductive layer on the support with a layer comprising said n-type semiconductor with a bandgap of greater than 2.9 eV; coating said n-type semiconductor-containing layer with a solution or dispersion comprising a cation of said 1,3,5-tris-aminophenyl-benzene compound to provide after drying a layer comprising said 1,3,5tris-aminophenyl-benzene compound; and applying a conductive layer to said layer comprising said 1,3,5-tris-aminophenyl-benzene compound thereby providing a second electrode.

8. A photovoltaic device comprising a n-type semiconductor with a band-gap of greater than 2.9 eV and a 1,3,5-tris-aminophenyl-benzene compound represented by formula (I): 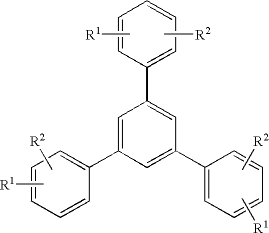
wherein R¹ represents a —NR³R⁴ group, wherein R³ and R⁴, same or different, represent an unsubstituted C₂-C₁₀ alkyl group, a substituted C₂-C₁₀ alkyl group, a benzyl group, an unsubstituted cycloalkyl group, a substituted cycloalkyl group, an unsubstituted aryl group or a substituted aryl group, and R² represents hydrogen, an alkyl group including a substituted alkyl group or halogen; and said 1,3,5-tris-aminophenyl-benzene compound.

9. Photovoltaic device according to claim 8, wherein said 1,3,5-tris-aminophenyl-benzene compound represented by formula (I) is selected from the group consisting of:

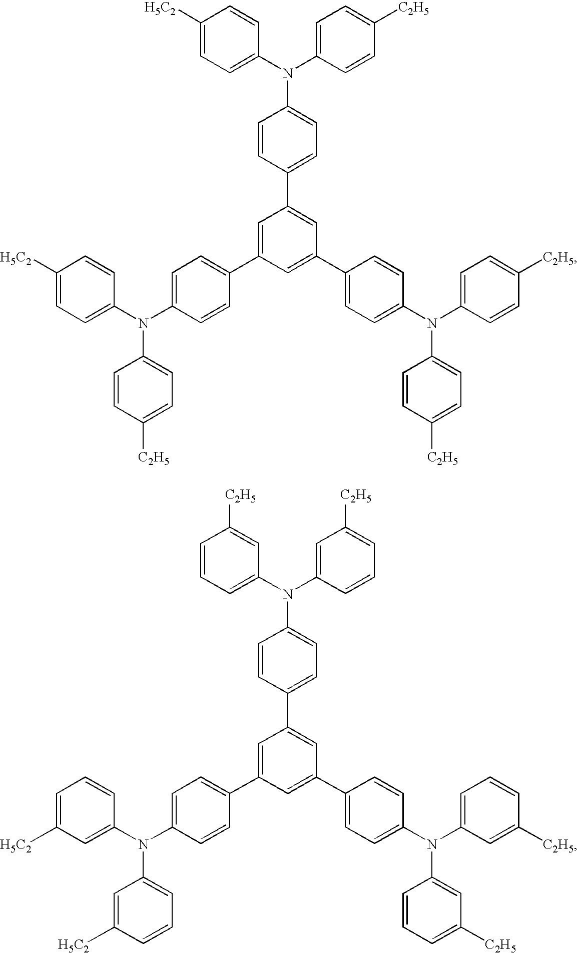

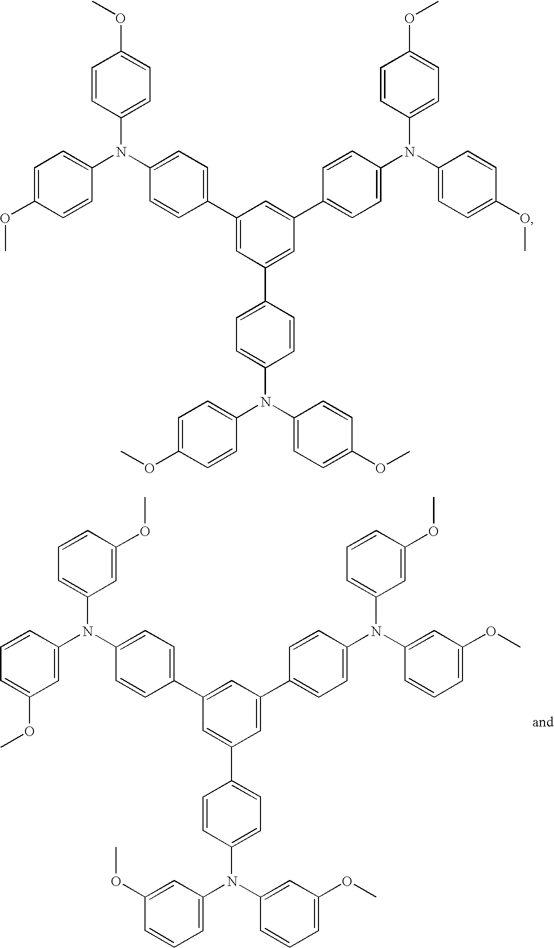

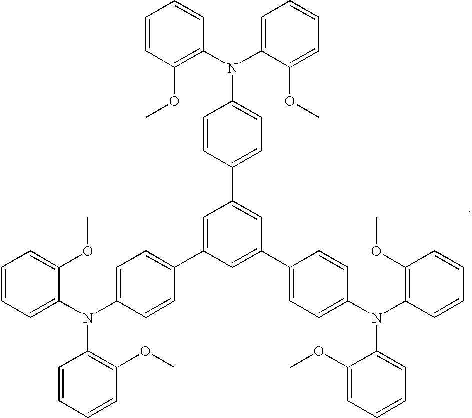

10. Photovoltaic device according to claim 8, wherein said n-type semiconductor is selected from the group consisting of titanium oxides, tin oxides, niobium oxides, tantalum oxides, tungsten oxides and zinc oxides.

11. Photovoltaic device according to claim 8, wherein said photovoltaic device further contains at least one spectral sensitizer.

12. Photovoltaic device according to claim 8, wherein said photovoltaic device further contains at least one spectral sensitizer selected from the group consisting of metal chalcogenide nano-particles with a band-gap of less than 2.9 eV, organic dyes and metallo-organic dyes.

13. Photovoltaic device according to claim 8, wherein said photovoltaic device further contains at least one spectral sensitizer selected from the group consisting metal oxides, metal sulphides and metal selenides.

14. A process for preparing a photovoltaic device comprising a n-type semiconductor with a band-gap of greater than 2.9.eV and a 1,3,5-tris-aminophenyl-benzene compound represented by formula (I): 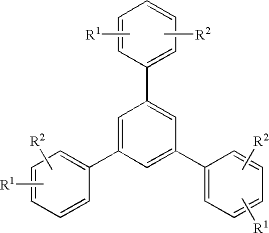
wherein R¹ represents a —NR³R⁴ group, wherein R³ and R⁴, same or different, represent an unsubstituted C₂-C₁₀ alkyl group, a substituted C₂-C₁₀ alkyl group, a benzyl group, an unsubstituted cycloalkyl group, a substituted cycloalkyl group, an unsubstituted aryl group or a substituted aryl group, and R² represents hydrogen,.an alkyl group including a substituted alkyl group or halogen with at least one transparent electrode comprising the steps of: providing a support with a conductive layer as one electrode; coating said conductive layer on the support with a layer comprising said n-type semiconductor with a bandgap of greater than 2.9 eV; coating said n-type semiconductor-containing layer with a solution or dispersion comprising said 1,3,5-tris-aminophenyl-benzene compound to provide after drying a layer comprising said 1,3,5-tris-aminophenyl-benzene compound; and applying a conductive layer to said layer comprising said 1,3,5-tris-aminophenyl-benzene compound thereby providing a second electrode.
